(19) United States
(12) Patent Application Publication
(10) Pub. No.: US 2007/0231970 A1
(43) Pub. Date: Oct. 4, 2007

(54) Cured mold compound spacer for stacked-die package

(76) Inventors: Tsuyoshi Fukuo, Tsukuba (JP); Tetsuhide Koh, Tsuchiura (JP); Seiji Ishiyama, Ushiku (JP); Kazuo Ogata, Tsukuba (JP)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/395,628

(22) Filed: Mar. 31, 2006

(51) Int. Cl. H01L 21/00

(52) U.S. Cl. 438/127

(57) ABSTRACT

An embodiment of the present invention is a technique to fabricate a package. A lower die is attached to a substrate. A stacked-die assembly having a spacer made of a cured mold compound is formed between the lower die and an upper die. The stacked-die assembly is encapsulated using the cured mold compound.

### FIELD OF THE INVENTION

Embodiments of the invention relate to the field of semiconductor, and more specifically, to semiconductor packaging.

### DESCRIPTION OF RELATED ART

The demand for small foot print and high density memory devices such as flash memories has led to many new packaging techniques. One technique is stacked-chip packaging where dice are stacked up in the same package. In these packages, spacers are inserted between adjacent dice to provide support and space for wiring.

Spacers used in stacked chip packages are typically made of silicon. Such uses of spacers have a number of disadvantages. First, de-lamination at the interface between the spacer and the mold compound may occur due to differences in their thermal and mechanical characteristics. Second, spacers made of silicon are typically expensive in manufacturing.

### BRIEF DESCRIPTION OF THE DRAWINGS

Embodiments of invention may best be understood by referring to the following description and accompanying drawings that are used to illustrate embodiments of the invention. In the drawings:

FIG. 1A is a diagram illustrating a manufacturing system in which one embodiment of the invention can be practiced.

FIG. 1B is a diagram illustrating a system according to one embodiment of the invention.

FIG. 2 is a diagram illustrating a package device according to one embodiment of the invention.

FIG. 3 is a diagram illustrating a process to package a stacked-die using a spacer and die attach sheets made of cured mold compound according to one embodiment of the invention.

FIG. 4 is a flowchart illustrating a process to package a device with stacked dice according to one embodiment of the invention.

FIG. 5 is a flowchart illustrating a process to form a stacked-die assembly according to one embodiment of the invention.

FIG. 6 is a flowchart illustrating a process to attach a cured spacer by die attach films according to one embodiment of the invention.

### DESCRIPTION

An embodiment of the present invention is a technique to fabricate a package. A lower die is attached to a substrate. A stacked-die assembly having a spacer made of a cured mold compound is formed between the lower die and an upper die. The stacked-die assembly is encapsulated using the cured mold compound.

In the following description, numerous specific details are set forth. However, it is understood that embodiments of the invention may be practiced without these specific details. In other instances, well-known circuits, structures, and techniques have not been shown to avoid obscuring the understanding of this description.

One embodiment of the invention may be described as a process which is usually depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a program, a procedure, a method of manufacturing or fabrication, etc.

An embodiment of the present invention is a technique to fabricate a stacked-die package. A spacer is placed between a lower die and an upper die. The spacer is made of the same cured mold compound as the encapsulant used to encapsulate the dice on a substrate. By using the spacer made of the cured mold compound of the encapsulant, delamination at the interface between the encapsulant and the spacer may be eliminated because the spacer is physically, thermally, and chemically matching with the surrounding encapsulant mold compound. In addition, the cost is reduced because the spacer made of cured mold compound is less expensive than spacer made of silicon or other materials. The cured mold compound is a hard solid that may sustain 20 to 30 Giga Pascal (GPa) and therefore is a good material for spacers.

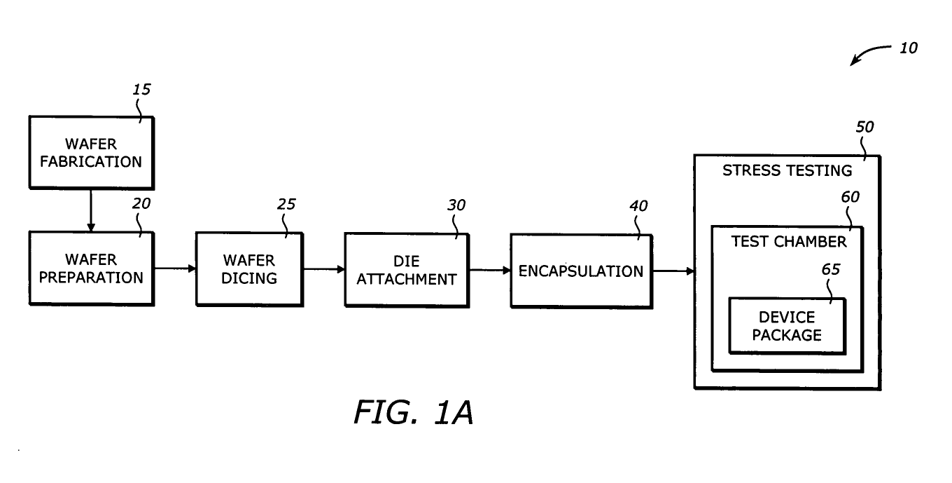

FIG. 1A is a diagram illustrating a manufacturing system 10 in which one embodiment of the invention can be practiced. The system 10 includes a wafer fabrication phase 15, wafer preparation phase 20, a wafer dicing phase 25, a die attachment phase 30, an encapsulation phase 40, and a stress testing phase 50. The system 10 represents a manufacturing flow of a semiconductor packaging process.

The wafer fabrication phase 15 fabricates the wafer containing a number of dice. The individual dice may be any microelectronic devices such as microprocessors, memory devices, interface circuits, etc. The wafer fabrication phase 15 includes typical processes for semiconductor fabrication such as preparation of the wafer surface, growth of silicon dioxide (SiO₂), patterning and subsequent implantation or diffusion of dopants to obtain the desired electrical properties, growth or deposition of a gate dielectric, and growth or deposition of insulating materials, depositing layers of metal and insulating material and etching it into the desired patterns. Typically the metal layers consist of aluminium or copper. The various metal layers are interconnected by etching holes, called “vias,” in the insulating material.

The wafer preparation phase 20 prepares a wafer containing dice for packaging and testing. During this phase, the wafers are sorted after the patterning process. An inspection may be carried out to check for wafer defects. Then, the wafer may be mounted on a backing tape that adheres to the back of the wafer. The mounting tape provides mechanical support for handling during subsequent phases.

The wafer dicing phase 25 dices, cuts, or saws the wafer into individual dice. High precision saw blade and image recognition unit may be used. De-ionized water may be dispensed on the wafer to wash away any residual particles or contaminants during the dicing. Then, the wafer is dried by being spun at high spinning speed.

The die attachment phase 30 attaches the die to a package substrate. The substrate material depends on the packaging type. It may be lead-frame, plastic, or epoxy. The substrate is fabricated to have a reduced layer count by using an external ground layer. The external ground layer may be a conductive layer, such as a copper foil, that is surface mounted on the substrate. The die attachment phase 30 may include assembling a stacked-die assembly with a spacer. Wire bonding may be performed to interconnect wires connecting the bond pads on the die or dice to the substrate.

The encapsulation phase 40 encapsulates the die and the substrate. Depending on the packaging type, this may include molding, wire bonding, and solder ball attachment. Underfill material may be dispensed between the die and the substrate. Integrated heat spreader (IHS) may be attached to the die and substrate assembly. In one embodiment, the stacked-die assembly is encapsulated with a cured mold compound. The encapsulated assembly of the die and substrate becomes a device package 65 ready to be tested.

The stress testing phase 50 performs one or more tests such as Highly Accelerated Stress Test (HAST) or biased-HAST on the device package under stress conditions. A test chamber 60 may be designed to conduct a stress test. It may have monitoring circuits, measurement circuits, and other data processing equipment. The package 65 is placed in the test chamber 60 subject to the stress test. It may be powered or non-powered. Various stress tests may be performed on the wafer or on the packaged devices 65 at various points of the manufacturing process flow. The tests may follow standards such as Joint Electron Device Engineering Council (JEDEC) standards or military standards. Examples of these tests may include electrostatic discharge (ESD), or human body model (HBM), high temperature operational life (HTOL), thermal shock, temperature cycle, high temperature storage, vibration and mechanical loading, shear testing, and accelerated moisture resistance.

FIG. 1B is a diagram illustrating a system 100 according to one embodiment of the invention. The system 100 represents a mobile communication module. It includes a system on package (SOP) 110, an intermediate frequency processing unit 160, and a base-band processing unit 170.

The SOP 110 represents the front end processing unit for the mobile communication module. It is a transceiver incorporating on-package integrated lumped passive components as well as radio frequency (RF) components. It includes an antenna 115, a duplexer 120, a filter 125, a system-on-chip (SOC) 150, a power amplifier (PA) 180, and a filter 185.

The antenna 115 receives and transmits RF signals. The RF signals may be converted to digital data for processing in subsequent stages. It is designed in compact micro-strip and strip-line for L and C-band wireless applications. The duplexer 120 acts as a switch to couple to the antenna 115 to the receiver and the transmitter to the antenna 115. The filters 125 and 185 are C-band LTCC-strip-line filter or multilayer organic lumped-element filter at 5.2 GHz and narrowband performance of 200 MHz suitable for the Institute of Electrical and Electronic Engineers (IEEE) 802.11 wireless local area network (WLAN). The SOC 150 includes a low noise amplifier (LNA) 130, a down converter 135, a local voltage controlled oscillator (VCO) 140, an up converter 171, and a driver amplifier 175. The LNA 130 amplifies the received signal. The down converter 135 is a mixer to convert the RF signal to the IF band to be processed by the IF processing unit 160. The up converter 171 is a mixer to convert the IF signal to the proper RF signal for transmission. The VCO 140 generates modulation signal at appropriate frequencies for down conversion and up conversion. The driver amplifier 175 drives the PA 180. The PA 180 amplifies the transmit signal for transmission.

The IF processing unit 160 includes analog components to process IF signals for receiving and transmission. It may include a band-pass filter and a low pass filter at suitable frequency bands. The filter may provide base-band signal to the base-band processing unit 170. The base-band processing unit 170 may include an analog-to-digital converter (ADC) 172, a digital-to-analog converter (DAC) 174, a digital signal processor (DSP) 176, and memory device 178. The ADC 172 and the DAC 174 are used to convert analog signals to digital data and digital data to analog signal, respectively. The DSP 176 is a programmable processor that may execute a program to process the digital data. The memory device 178 may be flash memories or random access memories. It may be packaged using Flip-Chip Ball Grid Array (FCBGA) packaging technology, a molded packaging, or any other suitable packaging technologies. The memory device 178 may be manufactured according to the manufacturing flow 10 shown in FIG. 1A. It may be the device package 65. It may include a stacked-die assembly in the package. The base-band processing unit 170 may also include memory and peripheral components. The DSP 176 may, therefore, be coupled to the front end processing unit via the IF processing unit 160 and/or the base-band processing unit 170 to process the digital data.

The SOP 110 may be a multi-layer three-dimensional (3D) architecture for a monolithic microwave integrated circuit (MMIC) with embedded passives (EP) technology. It may be implemented using Low Temperature Co-fired Ceramics (LTCC) and organic-based technologies. The 3D architecture may include multiple layers include a layer 117 to implement the antenna 115, layers 122, 124, and 186 for the filters 125 and 185, and layer 188 for the SOC 150 and the passive components using EP technology. Typically, the packaging technology involves embedded passives with multiple layers.

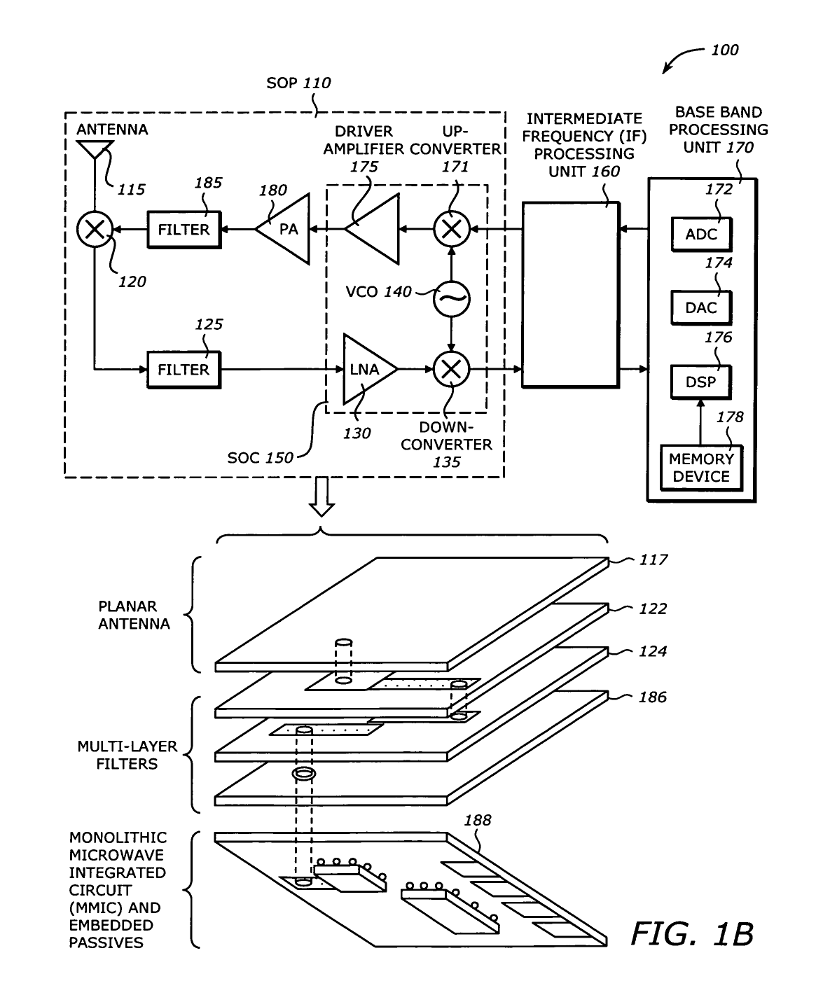

FIG. 2 is a diagram illustrating the package device 65 or 178 shown in FIG. 1A and FIG. 1B, respectively, according to one embodiment of the invention. The package device 65/178 includes a substrate 210, an encapsulant 220, a stacked-die assembly 230, and solder balls 240.

The substrate 210 is a package substrate that provides support for the stacked-die assembly 230. The substrate 210 may be polymer or a composite. The substrate 210 may be selected for any suitable packaging technologies including molded packaging, Ball Grid Array (BGA), Pin Grid Array (PGA), or Land Grid Array (LGA). The substrate 210 may be attached to a number of solder balls 240. The solder balls 240 allow attachment of the package device 65/178 to a circuit board or to any other mounting component.

The encapsulant 220 encapsulates the stacked-die assembly 220 over the substrate 210. The encapsulant 220 may be made of a cured mold compound. The mold compound may be made by epoxy such as bisphenol, or phenolic resin, etc. It may include hardener such as anhydrides, amines, and filler such as silica.

The stacked-die assembly 230 includes at least a lower die 250, a spacer 260, and an upper die 270. The stacked-die assembly 230 may contain more than two dice and more than one spacer. Each of the lower and upper dice 250 and 270 may be any semiconductor die. It may have a microelectronic device such as a microprocessor, a memory, an interface chip, an integrated circuit, etc. The stacked-die assembly 230 is attached to the substrate 210 by a die attach element 235. The die attach element 235 may be a die-attach film, paste, or adhesive made of a material different than the cured mold compound of the encapsulant 220. The die attach adhesive may be Bismaleimide resin-based or made of epoxy resin mixed with hardener, filler and other additives. It may also be a die attach sheet made of the same cured mold compound as the encapsulant 220.

The spacer 260 is made by the same cured mold compound as the encapsulant 220. It may be attached to the lower die 250 by a die attach element 255 and to the upper die 270 by a die attach element 265. In one embodiment, the die attach elements 255 and 265 are die attach films or pastes that are made of material different that the cured mold compound. In another embodiment, the die attach elements 255 and 265 are die attach sheets that are made of the same cured mold compound as the encapsulant 220.

The lower die 250 and the upper die 270 are connected to the substrate 210 by interconnecting wires 280. The interconnecting wires 280 are connected to bond pads on the lower die 250 and the upper die 270 and contact pads on the substrate 210.

Since the spacer is made of the same material as the encapsulant, its thermal, physical, and chemical properties match with the encapsulant. For example, their coefficients of thermal expansion (CTEs) match. Accordingly, any thermal or mechanical risks are reduced. Delamination at the interface of the encapsulant and the spacer may be reduced. When the die attach elements are also made of the cured mold compound, the risks are further reduced. Since the spacer, the die attach sheets, and the encapsulant are made of the same cured mold compound, they become homogeneous. The spacer and the die attach sheets may become invisible under X-ray inspection.

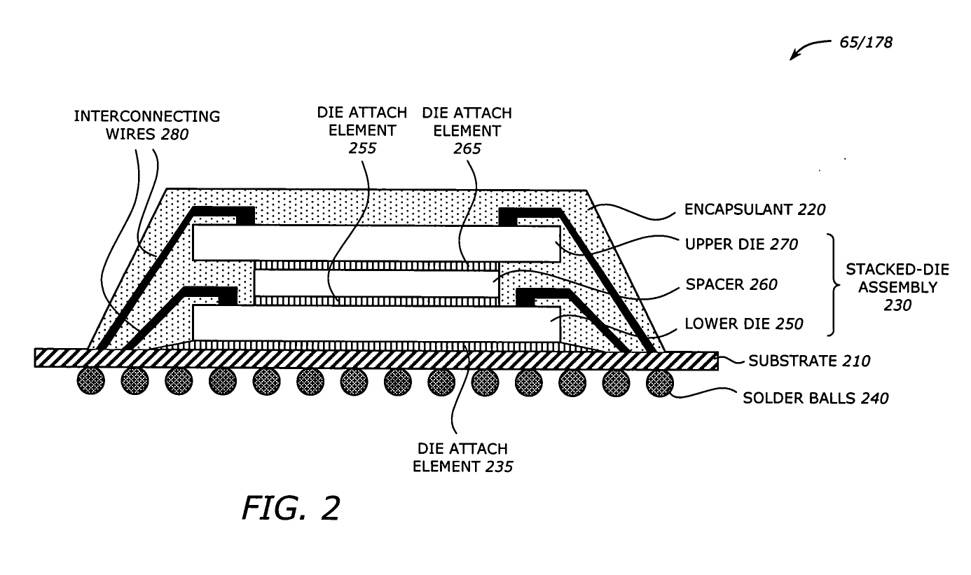

FIG. 3 is a diagram illustrating a process 300 to package a stacked-die using a spacer and die attach sheets made of cured mold compound according to one embodiment of the invention.

An uncured mold compound powder 310 is tabletized to form tablets 320. The tablets 320 is then melted and cured by a melting and curing process 315 to form the encapsulant 220 that encapsulates the stacked-die assembly 230. It is also melted and cured by a melting and curing process 325 to form a spacer 330.

The powder 310 is also used to form layers 340. The uncured layers 340 are then placed on both sides of the spacer 330 to sandwich the spacer 330. The layers 340 and the spacer 330 are then pressed by a press tool 345 to form a spacer assembly 350. The spacer assembly 350 is then attached to the lower die and upper die to form the stacked-die assembly 230. Then the stacked-die 230 is cured by a curing process 355. The curing temperature may range from room temperature to 150° C. The curing time period may be several minutes to an hour. The uncured layers 340 become the die attach elements 255 and 265 to attach the spacer 260 to the lower die 250 and the upper die 270, respectively. The powder 310 is also used to form an uncured die attach sheet 360. The die attach sheet 360 is melted and cured by a melting and curing process 365 to become the die attach element 235 to attach the stacked-die assembly 230 to the substrate 210.

Post mold cure (PMC) may also be performed for the package to further enhance reliability and reduce crack or other mechanical or thermal failures.

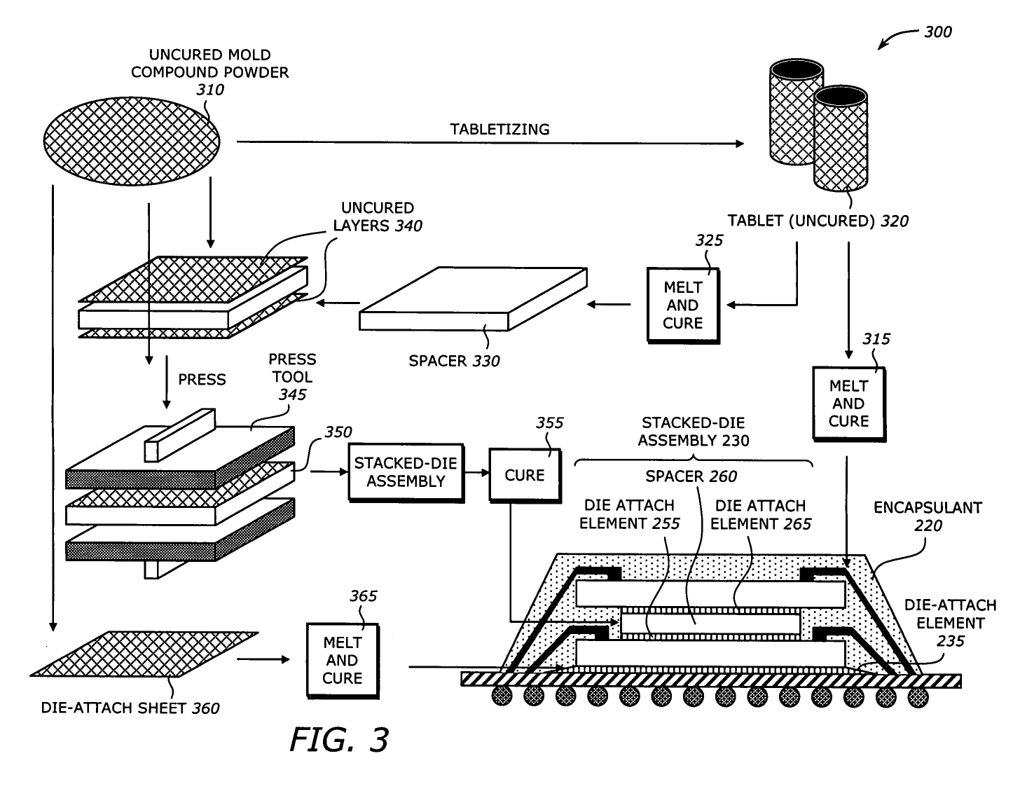

FIG. 4 is a flowchart illustrating a process 400 to package a device with stacked dice according to one embodiment of the invention.

Upon START, the process 400 attaches a lower die to a substrate (Block 410). The lower die may be attached to the substrate using a die attach film or a cured mold compound die attach sheet. Then, the process 400 forms a stacked-die assembly having a spacer made of a cured mold compound between the lower die and an upper die (Block 420). Next, the process 400 encapsulates the stacked-die assembly using the cured mold compound (Block 430). The process 400 is then terminated.

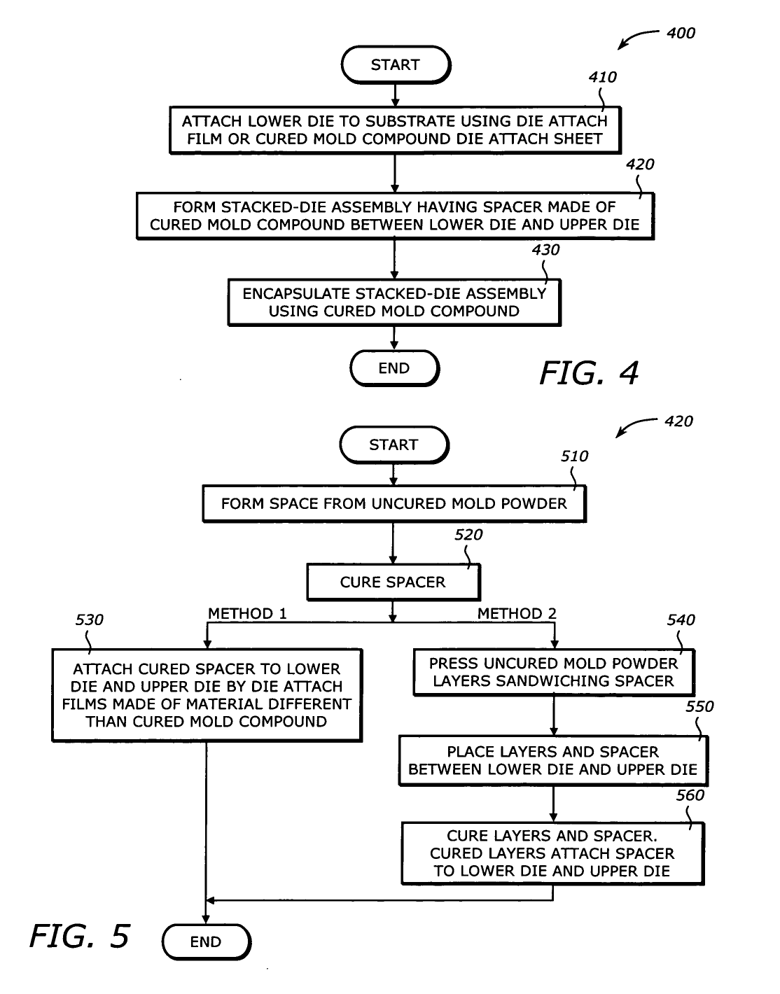

FIG. 5 is a flowchart illustrating the process 420 shown in FIG. 4 to form a stacked-die assembly according to one embodiment of the invention.

Upon START, the process 420 forms the spacer from uncured mold powder (Block 510). Next, the process 420 cures the spacer at appropriate temperature (Block 520). Then, the process 420 has two methods. For the first method, the process 420 attaches the cured spacer to the lower die and the upper die by die attach films made of material different than cured mold compound (Block 530) and is then terminated. For the second method, the process 420 presses uncured mold powder layers sandwiching the spacer (Block 540). Then, the process 420 places the uncured layers and the spacer between the lower die and the upper die (Block 550). Next, the process 420 cures the layers and the spacer (Block 560). The cured layers attach the spacer to the lower die and the upper die. The process 420 is then terminated.

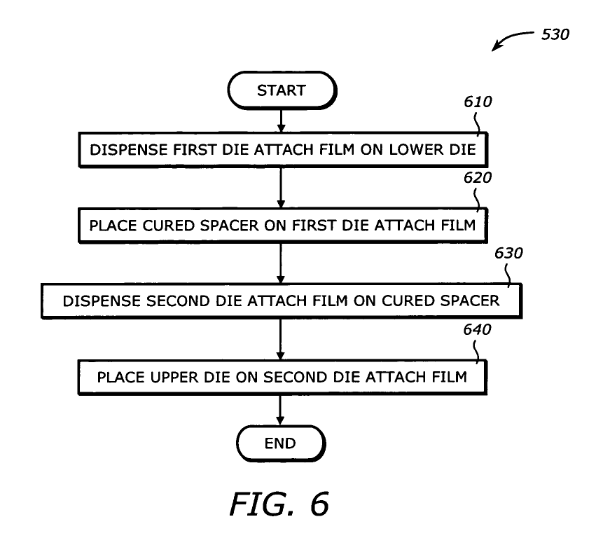

FIG. 6 is a flowchart illustrating the process 530 shown in FIG. 5 to attach a cured spacer by die attach films according to one embodiment of the invention.

Upon START, the process 530 dispenses a first die attach film on the lower die (Block 610). Then, the process 530 places the cured spacer on the first die attach film (Block 620). The first die attach film attaches the cured spacer to the lower die. Next, the process 530 dispenses a second die attach film on the cured spacer (Block 630). Then, the process 530 places the upper die on the second die attach film (Block 640). The second die attach film attaches the cured spacer to the upper die. The process 530 is then terminated.

Embodiments of the invention have been described with a package having a stacked-die assembly. The stacked-die assembly attached to a substrate. It includes a spacer made of a cured mold compound placed between a lower die and an upper die. The stacked-die assembly is encapsulated over the substrate by an encapsulant made of the same cured mold compound as the spacer. The spacer may be attached to the lower die and the upper die by die attach films or pastes that are made of a material different than the cured mold compound or by die attach sheets made of the same cure mold compound. Similarly, the lower die may be attached to the substrate by a die attach film or paste that is made of a material different than the cured mold compound or by die attach sheets made of the same cure mold compound. Using the same cured mold compound for encapsulant and spacer reduces thermal or mechanical failures due to CTE mismatches. Additionally, when the die attach sheets are also made of the same cured mold compound, the reliability of the package is further enhanced.

While the invention has been described in terms of several embodiments, those of ordinary skill in the art will recognize that the invention is not limited to the embodiments described, but can be practiced with modification and alteration within the spirit and scope of the appended claims. The description is thus to be regarded as illustrative instead of limiting.

What is claimed is:

1. A method comprising:
attaching a lower die to a substrate;
forming a stacked-die assembly having a spacer made of a cured mold compound between the lower die and an upper die; and
encapsulating the stacked-die assembly using the cured mold compound.

2. The method of claim 1 wherein forming the stacked-die assembly comprises:
forming the spacer from uncured mold powder; and
curing the spacer.

3. The method of claim 2 wherein forming the stacked-die assembly further comprises:
attaching the cured spacer to the lower die and upper die by die attach films made of material different than the cured mold compound.

4. The method of claim 3 wherein attaching the cured spacer comprises:
dispensing a first die attach film on the lower die;
placing the cured spacer on the first die attach film;
dispensing a second die attach film on the cured spacer; and
placing the upper die on the second die attach film.

5. The method of claim 2 wherein forming the stacked-die assembly further comprises:
pressing uncured mold powder layers sandwiching the spacer;
placing the layers and the spacer between the lower die and the upper die; and
curing the layers and the spacer, the cured layers attaching the spacer to the lower die and the upper die.

6. The method of claim 1 wherein attaching the lower die to the substrate comprises:
attaching the lower die to the substrate using a die attach film or a cured mold compound die attach sheet.

7. A package comprising:
a stacked-die assembly attached to a substrate, the stacked-die assembly comprising a spacer made of a cured mold compound placed between a lower die and an upper die; and
an encapsulant made of the cured mold compound to encapsulate the stacked-die assembly over the substrate.

8. The package of claim 7 wherein the stacked-die assembly further comprises:
a first die attach film to attach the spacer to the lower die; and
a second die attach film to attach the spacer to the upper die, the first and second die attach films being made of material different that the cured mold compound.

9. The package of claim 7 wherein the stacked-die assembly further comprises:
a first die attach sheet to attach the spacer to the lower die; and
a second die attach sheet to attach the spacer to the upper die, the first and second die attach sheets being made of the cured mold compound.

10. The package of claim 7 wherein the stacked-die assembly is attached to the substrate by a die attach film or a cured mold compound sheet.

11. The package of claim 7 further comprising:
interconnecting wires bonded to the lower die and the upper die and the substrate.

12. A system comprising:
a front end processing unit to receive and transmit a radio frequency (RF) signal, the RF signal being converted to digital data;
a digital processor coupled to the front end processing unit to process the digital data; and
a memory device coupled to the digital processor, the memory device being packaged in a package, the package comprising:
a stacked-die assembly attached to a substrate, the stacked-die assembly comprising a spacer made of a cured mold compound placed between a lower die and an upper die; and
an encapsulant made of the cured mold compound to encapsulate the stacked-die assembly over the substrate.

13. The system of claim 12 wherein the stacked-die assembly further comprises:
a first die attach film to attach the spacer to the lower die; and
a second die attach film to attach the spacer to the upper die, the first and second die attach films being made of material different that the cured mold compound.

14. The system of claim 12 wherein the stacked-die assembly further comprises:
a first die attach sheet to attach the spacer to the lower die; and
a second die attach sheet to attach the spacer to the upper die, the first and second die attach sheets being made of the cured mold compound.

15. The system of claim 12 wherein the stacked-die assembly is attached to the substrate by a die attach film or a cured mold compound sheet.

16. The system of claim 12 wherein the package further comprises:
interconnecting wires bonded to the lower die and the upper die and the substrate.
